(19) United States
(12) Patent Application Publication
(10) Pub. No.: US 2026/0143767 A1
(43) Pub. Date: May 21, 2026

(54) SEMICONDUCTOR DEVICE

(71) Applicant: FUJI ELECTRIC CO., LTD., Kanagawa (JP)

(72) Inventor: Koh YOSHIKAWA, Matsumoto-city (JP)

(21) Appl. No.: 19/334,928

(22) Filed: Sep. 21, 2025

(30) Foreign Application Priority Data
Nov. 18, 2024 (JP) 2024-200754

(51) Int. Cl. H10D 62/13; H10D 12/00; H10D 62/10; H10D 64/00

(52) U.S. Cl. CPC H10D 62/145; H10D 12/481; H10D 62/127; H10D 64/117

(57) ABSTRACT

A semiconductor device is provided in which an emitter region includes a first emitter portion which is in contact with a front surface of a semiconductor substrate, a second emitter portion which is provided below the first emitter portion and has a doping concentration lower than that of the first emitter portion, and a third emitter portion which is provided below the second emitter portion and has a doping concentration higher than that of the second emitter portion, and a gate trench portion includes a dummy conductive portion at an emitter potential, which is provided above the gate conductive portion, in a trench.

The contents of the following patent application(s) are incorporated herein by reference:
NO. 2024-200754 filed in JP on Nov. 18, 2024.

### BACKGROUND

### 1. Technical Field

The present invention relates to a semiconductor device.

### 2. Related Art

Conventionally, in a semiconductor device such as an insulated gate bipolar transistor (IGBT), a technique of changing an arrangement of an emitter region or the like to adjust characteristics is known (see, for example, Patent Documents 1 to 3).

Patent Document 1: Japanese Patent Application Publication No. 2008-91491

Patent Document 2: Japanese Patent Application Publication No. H10-173170

Patent Document 3: Japanese Patent Application Publication No. H9-283755

### BRIEF DESCRIPTION OF THE DRAWINGS

FIG. 1 is a top view illustrating an example of a semiconductor device 100.

FIG. 2 is an example of an enlarged view of a region D in FIG. 1.

FIG. 3 is a view illustrating an example of a cross section taken along line a-a of FIG. 2.

FIG. 4 illustrates a relationship between a doping concentration distribution and an electron concentration distribution according to an example.

FIG. 5 illustrates a relationship between the doping concentration distribution and the electron concentration distribution according to a comparative example.

FIG. 6 is a diagram illustrating another example of the cross section taken along line a-a in FIG. 2.

FIG. 7 is a diagram illustrating another example of the cross section taken along line a-a in FIG. 2.

FIG. 8 is a diagram illustrating another example of the cross section taken along line a-a in FIG. 2.

FIG. 9 is another example of an enlarged view of the region D in FIG. 1.

FIG. 10A is a view illustrating an example of a cross section taken along line b-b in FIG. 9.

FIG. 10B is a view illustrating an example of a cross section taken along line c-c in FIG. 9.

FIG. 10C is a view illustrating an example of a cross section taken along line d-d in FIG. 9.

FIG. 11 is another example of the enlarged view of the region D in FIG. 1.

FIG. 12A is a view illustrating an example of a cross section taken along line e-e in FIG. 9.

FIG. 12B is a view illustrating an example of a cross section taken along line f-f in FIG. 9.

### DESCRIPTION OF EXEMPLARY EMBODIMENTS

The present invention will be described below through embodiments of the invention, but the following embodiments do not limit the invention according to the claims. In addition, not all combinations of features described in the embodiments are essential to a solution of the invention.

In the present specification, one side in a direction parallel to a depth direction of a semiconductor substrate is referred to as “upper” or “front” and another side is referred to as “lower” or “back”. One surface of two principal surfaces of a substrate, a layer or other member is referred to as an upper surface or a front surface, and another surface is referred to as a lower surface or a back surface. “Upper”, “lower”, “front”, and “back” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate a height direction with respect to a ground. Note that a +Z axis direction and a −Z axis direction are directions opposite to each other. When a Z axis direction is described without describing signs, it means that the direction is parallel to a +Z axis and a −Z axis.

In the present specification, orthogonal axes parallel to the front surface and the back surface of the semiconductor substrate are referred to as the X axis and the Y axis. In addition, an axis perpendicular to the front surface and the back surface of the semiconductor substrate is referred to as the Z axis. As used herein, a direction of the Z axis may be referred to as the depth direction. In addition, as used herein, a direction parallel to the front surface and the back surface of the semiconductor substrate may be referred to as a horizontal direction, including the X axis and the Y axis.

A region from a center in the depth direction of the semiconductor substrate to the front surface of the semiconductor substrate may be referred to as a front surface side. Similarly, a region from the center in the depth direction of the semiconductor substrate to the back surface of the semiconductor substrate may be referred to as a back surface side.

In the present specification, a case where a term such as “same” or “equal” is mentioned may include a case where an error due to a variation in manufacturing or the like is included. The error is, for example, within 10%.

In the present specification, a conductivity type of a doping region doped with impurities is described as a P type or an N type. As used herein, the impurities may particularly mean either a donor of the N type or an acceptor of the P type, and may be described as a dopant. As used herein, the doping means introducing the donor or the acceptor into the semiconductor substrate and turning it into a semiconductor presenting a conductivity type of the N type, or a semiconductor presenting a conductivity type of the P type.

In the present specification, a doping concentration means a concentration of the donor or a concentration of the acceptor in a thermal equilibrium state. As used herein, a net doping concentration means a net concentration obtained by adding a donor concentration set as a positive ion concentration to an acceptor concentration set as a negative ion concentration, taking into account of polarities of charges. As an example, when the donor concentration is N_{D} and the acceptor concentration is N_{A}, the net doping concentration at any position is given as N_{D}-N_{A}. As used herein, the net doping concentration may be simply described as the doping concentration.

The donor has a function of supplying electrons to the semiconductor. The acceptor has a function of receiving electrons from the semiconductor. The donor and acceptor are not limited to the impurities themselves. For example, a VOH defect in which a vacancy (V), oxygen (O), and hydrogen (H) present in the semiconductor are attached together functions as the donor which supplies electrons. In the present specification, the VOH defect may be referred to as a hydrogen donor.

In the present specification, a description of a P+ type or an N+ type means a higher doping concentration than that of the P type or the N type, and a description of a P− type or an N− type means a lower doping concentration than that of the P type or the N type. As used herein, a unit system is an SI unit system unless otherwise noted. Although a unit of a length may be expressed in cm, various calculations may be performed after conversion to meters (m).

A chemical concentration in the present specification refers to an atomic density of impurities measured regardless of an electrical activation state. The chemical concentration (atomic density) can be measured by, for example, secondary ion mass spectrometry (SIMS). The net doping concentration described above can be measured by capacitance-voltage profiling (CV profiling). In addition, a carrier concentration measured by spreading resistance profiling (SRP method) may be set as the net doping concentration. The carrier concentration measured by the CV profiling or the SRP method may be a value in a thermal equilibrium state. In addition, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. As used herein, the doping concentration of the region of the N type may be referred to as the donor concentration, and the doping concentration of the region of the P type may be referred to as the acceptor concentration.

When a concentration distribution of the donor, acceptor, or net doping has a peak in a region, a value of the peak may be defined as the concentration of the donor, acceptor, or net doping in the region. In a case where the concentration of the donor, acceptor or net doping is substantially uniform in a region, or the like, an average donor, acceptor or net doping concentration in the region may be defined as a donor, acceptor or net doping concentration. In the present specification, atoms/cm³ or /cm³ is used to express a concentration per unit volume. This unit is used for the donor or acceptor concentration or the chemical concentration in the semiconductor substrate. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. A decrease in carrier mobility occurs when carriers are scattered due to disorder of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron serving as an acceptor is approximately 99% of chemical concentrations of these. On the other hand, in the silicon semiconductor, a donor concentration of hydrogen serving as a donor is approximately 0.1% to 10% of a chemical concentration of hydrogen. Each concentration in the present specification may be a value at room temperature. As an example, a value at 300K (Kelvin) (substantially 26.9 degrees C.) may be used for a value at room temperature.

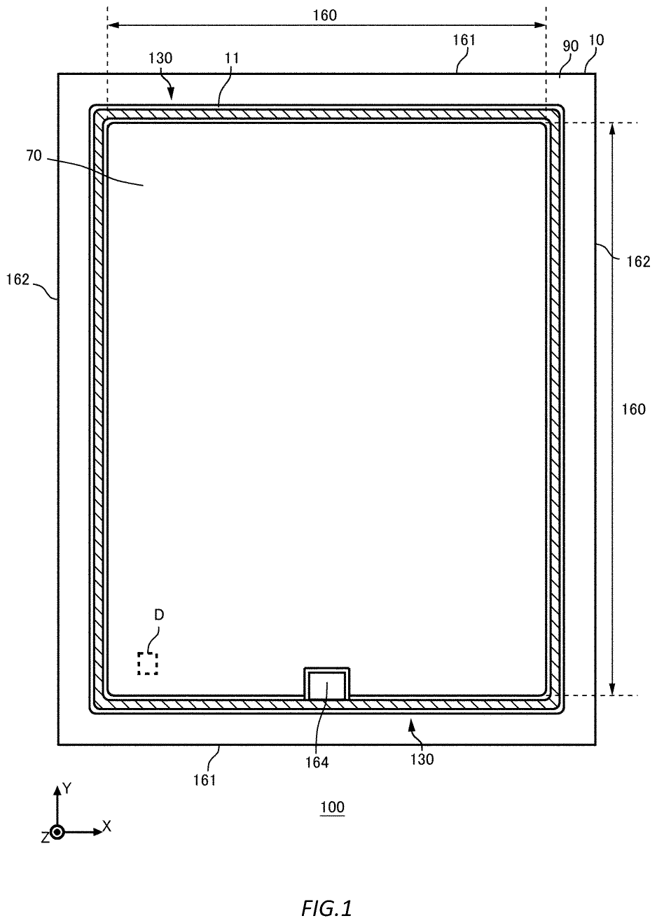

FIG. 1 is a top view illustrating an example of a semiconductor device 100. FIG. 1 illustrates a position of each member as being projected onto a front surface of a semiconductor substrate 10. FIG. 1 illustrates only some members of the semiconductor device 100, and illustration of some members is omitted.

The semiconductor device 100 includes the semiconductor substrate 10. The semiconductor substrate 10 is a substrate which is formed of a semiconductor material. Although the semiconductor substrate 10 is a silicon substrate by way of example, the material of the semiconductor substrate 10 is not limited to silicon. A material of the semiconductor substrate 10 may be silicon carbide (SiC), gallium nitride (GaN), or the like.

The semiconductor substrate 10 has a first end side 161 and a second end side 162 in a top view. In the present specification, unless otherwise specified, a top view means a view from the front surface side of the semiconductor substrate 10. The semiconductor substrate 10 of the present example has two sets of first end sides 161 facing each other in a top view. In addition, the semiconductor substrate 10 of the present example has two sets of second end sides 162 facing each other in a top view. In FIG. 1, the first end side 161 is parallel to an X axis direction. The second end side 162 is parallel to a Y axis direction. In addition, the Z axis is perpendicular to the front surface of the semiconductor substrate 10. In addition, the first end sides 161 are perpendicular to an extending direction or a longitudinal direction of a gate trench portion which will be described below. The second end sides 162 are parallel to the extending direction or the longitudinal direction of the gate trench portion which will be described below.

The semiconductor substrate 10 is provided with an active portion 160. The active portion 160 is a region where a principal current flows in the depth direction between the front surface and the back surface of the semiconductor substrate 10 when the semiconductor device 100 operates. An emitter electrode pad or the like is provided above the active portion 160, but is omitted in FIG. 1.

In the present example, the active portion 160 is provided with a transistor portion 70 including a transistor element such as an IGBT. In another example, the transistor portion 70 and a diode portion including a diode element such as a free wheel diode (FWD) may be alternately arranged along a predetermined array direction at the front surface of the semiconductor substrate 10. Although one transistor portion 70 is provided in the present example, a plurality of transistor portions 70 may also be provided. A well region of the P+ type or a gate runner may be provided between the transistor portions 70.

The transistor portion 70 includes a collector region of the P+ type in a region in contact with the back surface of the semiconductor substrate 10. In addition, in the transistor portion 70, an emitter region of the N+ type, a base region of the P− type, a drift region of the N− type, and a surface MOS structure having a gate conductive portion, and a gate dielectric film are periodically arranged on the front surface side of the semiconductor substrate 10.

The semiconductor device 100 may include one or more pads above the semiconductor substrate 10. The semiconductor device 100 in the present example includes a gate pad 164. The semiconductor device 100 may include a pad such as an anode pad, a cathode pad, and a current detection pad. Each pad is arranged in a vicinity of the first end side 161. The vicinity of the first end side 161 refers to a region between the first end side 161 and the emitter electrode in a top view. When the semiconductor device 100 is mounted, each pad may be connected to an external circuit via a wiring such as a wire.

A gate potential is applied to the gate pad 164. The gate pad 164 is electrically connected to a conductive portion of a gate trench portion of the active portion 160. The semiconductor device 100 includes a gate runner 130 that connects the gate pad 164 and the gate trench portion. In FIG. 1, the gate runner 130 is hatched with oblique lines.

The gate runner 130 is arranged between the active portion 160 and the first end side 161 or the second end side 162 in a top view. The gate runner 130 of the present example encloses the active portion 160 in a top view. A region enclosed by the gate runner 130 in a top view may be the active portion 160. The gate runner 130 is connected to the gate pad 164. The gate runner 130 is arranged above the semiconductor substrate 10. The gate runner 130 may be a metal wiring including aluminum or the like. The gate runner 130 may be provided separate from the emitter electrode.

A P type outer circumferential well region 11 is provided so as to overlap the gate runner 130. That is, similarly to the gate runner 130, the P type outer circumferential well region 11 encloses the active portion 160 in a top view. The P type outer circumferential well region 11 is provided so as to extend with a predetermined width also in a range not overlapping the gate runner 130. The P type outer circumferential well region 11 is a region of a second conductivity type. The P type outer circumferential well region 11 of the present example is of the P+ type.

The semiconductor device 100 may include a temperature sensing unit (not illustrated) which is a PN junction diode formed of polysilicon or the like, and a current detection unit (not illustrated) which simulates an operation of the transistor portion 70 provided in the active portion 160. The temperature sensing unit may be connected to the anode pad and the cathode pad via a wiring. When the temperature sensing unit is provided, the temperature sensing unit is preferably provided at a center of the semiconductor substrate 10 in the X axis direction and the Y axis direction.

The semiconductor device 100 of the present example includes an edge termination structure portion 90 between the active portion 160 and the first end side 161 or the second end side 162 in a top view. The edge termination structure portion 90 of the present example is arranged between the outer circumferential gate runner 130 and the first end side 161 or the second end side 162. The edge termination structure portion 90 reduces electric field strength on the front surface side of the semiconductor substrate 10. The edge termination structure portion 90 may include at least one of a guard ring, a field plate, or a RESURF which are annularly provided enclosing the active portion 160.

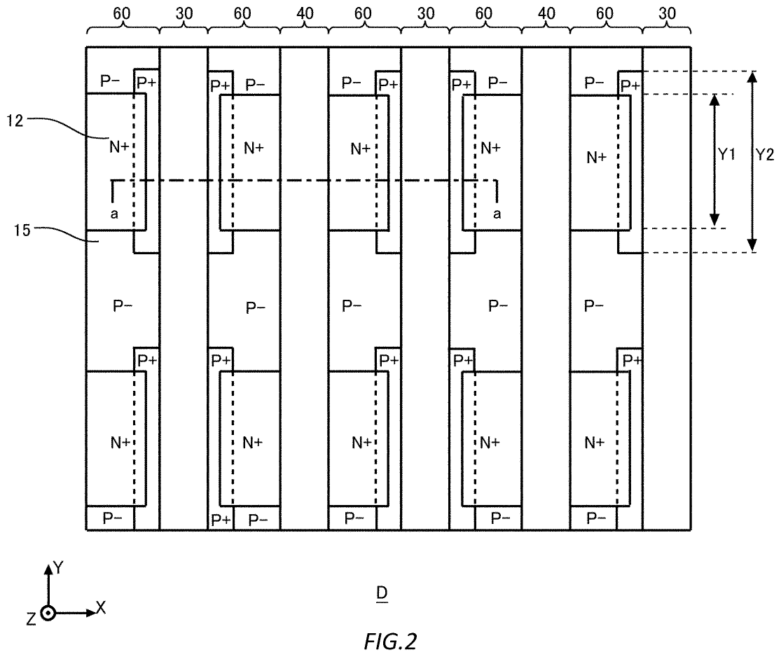

FIG. 2 is an example of an enlarged view of a region D in FIG. 1. The region D is a region which includes the transistor portion 70 of the active portion 160 illustrated in FIG. 1. FIG. 2 illustrates a structure of the front surface of the semiconductor substrate 10 in the region D. An interlayer dielectric film 38 and an emitter electrode 52 are provided above the front surface of the semiconductor substrate 10, but are omitted in FIG. 2. In the region D, the semiconductor device 100 includes one or more gate trench portions 40, one or more emitter regions 12, and one or more contact regions 15. The semiconductor device 100 may further include one or more dummy trench portions 30. In the present specification, the gate trench portion 40 and the dummy trench portion 30 may be each referred to as a trench portion. When a term “trench portion” is simply mentioned in the present specification, the trench portion may be either the gate trench portion 40 or the dummy trench portion 30.

The gate trench portion 40 is elongated in a first direction at the front surface of the semiconductor substrate 10. In the present example, the gate trench portion 40 is provided to extend in the Y axis direction which is the first direction. The gate trench portion 40 is provided from the front surface of the semiconductor substrate 10 to an inside of the semiconductor substrate 10. A gate conductive portion formed of a conductive material such as polysilicon is arranged inside the gate trench portion 40. The gate conductive portion is electrically connected to the gate runner 130 (see FIG. 1), and a predetermined gate voltage is applied thereto.

A plurality of trench portions are arrayed at predetermined intervals in a second direction intersecting with the first direction. The second direction in the present example is the X axis direction orthogonal to the first direction (Y axis direction). In the present example, a trench portion adjacent to the gate trench portion 40 in the X axis direction may be the dummy trench portion 30. As illustrated in FIG. 2, a trench portion adjacent to the dummy trench portion 30 in the X axis direction may be the gate trench portion 40 or the dummy trench portion 30. One or more dummy trench portions 30 may be arranged between two gate trench portions 40 in the X axis direction. However, in another example, the dummy trench portions 30 may not be provided, and the gate trench portions 40 may be arranged adjacent to each other in the X axis direction.

A region of the semiconductor substrate 10 sandwiched between two trench portions in the X axis direction is defined as a mesa portion 60. Each end of the mesa portion 60 in the X axis direction is a boundary portion with each trench portion. A depth position of a lower end of the mesa portion 60 is to be the same as a depth position of a lower end of at least one of the trench portions on both sides.

The emitter region 12 is a region of a first conductivity type provided to be exposed on the front surface of the semiconductor substrate 10. As an example, the first conductivity type is the N type. The emitter region 12 is in contact with the gate trench portion 40. The emitter region 12 may be provided in each mesa portion 60 in contact with the gate trench portion 40. Each emitter region 12 may have a band shape elongated in the Y axis direction, or may have a rectangular shape. A length of one emitter region 12 in the Y axis direction is defined as Y1. Since each of the emitter regions 12 is elongated in the Y axis direction, a length, in the Y axis direction, of a channel formed below the emitter region 12 can be increased, and a channel density can be improved. The emitter region 12 may be in contact with only one trench portion (the gate trench portion 40 in FIG. 2) of the trench portions on both sides of the mesa portion 60, and may not be in contact with another trench portion (the dummy trench portion 30 in FIG. 2).

As illustrated in FIG. 2, in one mesa portion 60, a plurality of emitter regions 12 may be discretely arranged in the Y axis direction. A distance between two emitter regions 12 which are adjacent to each other in the Y axis direction may be smaller than the length Y1, or may be less than or equal to half, one fourth, or one tenth of the length Y1. In another example, only one emitter region 12 may be continuously arranged in one mesa portion 60 in the Y axis direction. In this case, the length Y1 of the emitter region 12 may be greater than or equal to half or three fourths of a length of the mesa portion 60 in the Y axis direction.

A contact region 15 is a region of the second conductivity type exposed on the front surface of the semiconductor substrate 10 in the mesa portion 60 and connected to the emitter electrode. As an example, the second conductivity type is the P type. The contact region 15 of the present example is a region of the P+ type having a higher doping concentration than that of a base region which will be described below. Since the contact region 15 has a higher doping concentration than that of the base region, a contact resistance between the contact region 15 and the emitter electrode can be reduced.

As illustrated in FIG. 2, in one mesa portion 60, a plurality of contact regions 15 may be discretely arranged in the Y axis direction. Each contact region 15 may have a band shape elongated in the Y axis direction, or may have a rectangular shape. In a top view of the semiconductor substrate 10, the contact region 15 may be arranged so as to overlap the emitter region 12. In FIG. 2, an end portion of the contact region 15 arranged below the emitter region 12 is indicated by a broken line. Assuming that a length of one contact region 15 in the Y axis direction is Y2, the length Y2 may be larger than the length Y1. Accordingly, a contact area between the contact region 15 and the emitter electrode can be expanded.

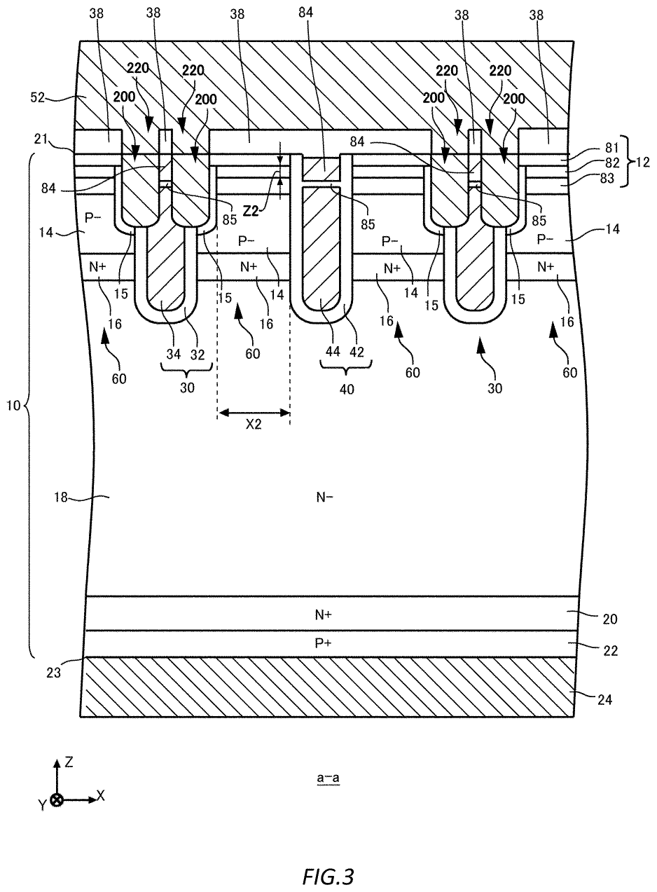

FIG. 3 is a view illustrating an example of a cross section taken along line a-a of FIG. 2. A cross section a-a is an XZ cross section passing through the emitter region 12 and the contact region 15. In the cross section, the semiconductor device 100 of the present example includes the semiconductor substrate 10, the interlayer dielectric film 38, the emitter electrode 52, and a collector electrode 24.

The emitter electrode 52 is provided above a front surface 21 of the semiconductor substrate 10. A part of the front surface 21 of the semiconductor substrate 10 is covered with the interlayer dielectric film 38. The emitter electrode 52 is in contact with at least a part of the front surface 21 of the semiconductor substrate 10 that is not covered with the interlayer dielectric film 38. The emitter electrode 52 of the present example is in contact with the contact region 15.

The emitter electrode 52 is formed of a material containing metal. For example, at least a partial region of the emitter electrode 52 is formed of aluminum or an aluminum-silicon alloy, for example, a metal alloy such as AlSi or AlSiCu. The emitter electrode 52 may have a barrier metal formed of titanium, titanium nitride, or the like below a region formed of aluminum or the like. The barrier metal may be in contact with the semiconductor substrate 10. The emitter electrode 52 may have a metal plug formed tungsten or the like below the region formed of aluminum or the like.

The collector electrode 24 is provided on a back surface 23 of the semiconductor substrate 10. The collector electrode 24 may be formed of a metal material such as aluminum similarly to the emitter electrode 52, or may be formed by laminating a plurality of different metal materials. In the present specification, a direction in which the emitter electrode 52 is connected to the collector electrode 24 (Z axis direction) is referred to as the depth direction.

The interlayer dielectric film 38 is provided on the front surface 21 of the semiconductor substrate 10. The interlayer dielectric film 38 is a film including at least one layer of a dielectric film such as silicate glass to which impurities such as boron or phosphorous are added, a thermal oxide film, or other dielectric films. The interlayer dielectric film 38 may cover each trench portion.

The interlayer dielectric film 38 of the present example has a plurality of contact holes 220. The contact holes 220 are provided between the emitter electrode 52 and the front surface 21 of the semiconductor substrate 10. The emitter electrode 52 is electrically connected to the front surface 21 of the semiconductor substrate 10 through the contact holes 220. The contact holes 220 are filled with the emitter electrode 52. The emitter electrode 52 may have a plug formed of tungsten or the like in the contact hole 220. The plug may be formed by forming a barrier metal on a side in contact with the semiconductor substrate 10 in the contact hole 220 and embedding tungsten so as to be in contact with the barrier metal.

Each mesa portion 60 is provided with a base region 14 of the P− type. The base region 14 is in contact with the gate trench portion 40. The base region 14 may be in contact with each of trench portions on both sides of the mesa portion 60. At least a part of the base region 14 is provided below the emitter region 12. The base region 14 may be in contact with the emitter region 12. When a predetermined ON voltage is applied to the gate trench portion 40, a surface layer of the base region 14 in contact with the gate trench portion 40 is inverted to a region of the N type to form a channel. The emitter region 12 is electrically connected by the channel to a drift region 18 which will be described below.

The base region 14 is provided also below the contact region 15. The base region 14 is in contact with the contact region 15. The base region 14 of the present example is a region of the P− type having a lower doping concentration than that of the contact region 15.

The semiconductor substrate 10 includes the drift region 18 of the N− type. The emitter region 12 has a higher doping concentration than the drift region 18. The drift region 18 is provided below the base region 14. An accumulation region 16 of the N+ type having a higher doping concentration than that of the drift region 18 may be provided between the drift region 18 and the base region 14. Providing the accumulation region 16 can produce an electron injection enhancement effect to decrease the ON voltage of the semiconductor device 100.

A collector region 22 of the P+ type is provided between the drift region 18 and the back surface 23 of the semiconductor substrate 10. A doping concentration of the collector region 22 is higher than a doping concentration of the base region 14. The collector region 22 may include an acceptor which is the same as or different from an acceptor of the base region 14. The acceptor of the collector region 22 is, for example, boron. The element serving as the acceptor is not limited to the example described above. The collector region 22 is exposed on the back surface 23 of the semiconductor substrate 10 and is connected to the collector electrode 24. The collector electrode 24 may be in contact with the entire back surface 23 of the semiconductor substrate 10.

A buffer region 20 of the N+ type may be provided between the drift region 18 and the collector region 22. A doping concentration of the buffer region 20 is higher than a doping concentration of the drift region 18. The buffer region 20 may have one or more concentration peaks with a doping concentration higher than that of the drift region 18. A doping concentration at a concentration peak refers to a doping concentration at a local maximum of the concentration peak. In addition, as the doping concentration of the drift region 18, an average value of doping concentrations in a region where a doping concentration distribution is substantially flat may be used.

The buffer region 20 may be formed by ion implantation of the dopant of the N type such as hydrogen (proton) or phosphorous. The buffer region 20 of the present example is formed by the ion implantation of hydrogen. The buffer region 20 may function as a field stopper layer which prevents a depletion layer expanding from a lower end of the base region 14 from reaching the collector region 22.

One or more gate trench portions 40 are provided at the front surface 21 of the semiconductor substrate 10. In the present example, a plurality of gate trench portions 40 are provided at the front surface 21 of the semiconductor substrate 10. In the present example, each gate trench portion 40 penetrates the base region 14 from the front surface 21 of the semiconductor substrate 10 and reaches the drift region 18. A structure in which the trench portion penetrates the doping region is not limited to a structure which is made by forming the doping region and then forming the trench portion in order. A structure in which the trench portion is formed and then the doping region is formed between the trench portions is also included in the structure in which the trench portion penetrates the doping region.

The gate trench portion 40 includes a groove-shaped gate trench, a gate dielectric film 42, and a gate conductive portion 44 which are provided at the front surface 21 of the semiconductor substrate 10. The gate conductive portion 44 is formed of polysilicon which is a conductive material. The gate dielectric film 42 is provided to cover an inner wall of the gate trench. The gate dielectric film 42 may be formed by oxidizing or nitriding a semiconductor on the inner wall of the gate trench. The gate conductive portion 44 is provided on an inner side further than the gate dielectric film 42 inside the gate trench. That is, the gate dielectric film 42 insulates the gate conductive portion 44 from the semiconductor substrate 10.

The gate conductive portion 44 in the gate trench portion 40 may be provided longer than the base region 14 in the depth direction. The gate trench portion 40 in the cross section is covered with the interlayer dielectric film 38 on the front surface 21 of the semiconductor substrate 10. The gate conductive portion 44 is electrically connected to the gate runner 130 at a position other than the cross section illustrated in FIG. 3.

The dummy trench portion 30 has a structure similar to that of the gate trench portion 40. The dummy trench portion 30 in the present example includes a groove-shaped dummy trench, a dummy dielectric film 32, and a dummy conductive portion 34. Structures of the dummy trench, the dummy dielectric film 32, and the dummy conductive portion 34 are similar to those of the gate trench, the gate dielectric film 42, and the gate conductive portion 44. The dummy trench portion 30 in the cross section is covered with the interlayer dielectric film 38 on the front surface 21 of the semiconductor substrate 10. The dummy conductive portion 34 is electrically connected to the emitter electrode 52 at a position other than the cross section illustrated in FIG. 3.

The semiconductor device 100 of the present example includes a trench contact portion 200 below the contact hole 220. The trench contact portion 200 is a recess formed from the front surface 21 of the semiconductor substrate 10 to the inside of the semiconductor substrate 10. The trench contact portion 200 of the present example is provided from the front surface 21 of the semiconductor substrate 10 to a position deeper than an upper end of the base region 14. The inside of the trench contact portion 200 is filled with the emitter electrode 52 similarly to the contact hole 220. The trench contact portion 200 may contain tungsten. The emitter electrode 52 and the semiconductor substrate 10 are in contact with each other on a side surface and a bottom surface of the trench contact portion 200. Accordingly, a contact area between the emitter electrode 52 and the semiconductor substrate 10 can be increased.

The trench contact portion 200 may be provided above the dummy trench portion 30. A plurality of trench contact portions 200 may be provided above the dummy trench portion 30. In the present example, two trench contact portions 200 are provided above one dummy trench portion 30. In another example, one trench contact portion 200 having a width larger than that of the dummy trench portion 30 in the X axis direction may be provided above one dummy trench portion 30. With such a structure, even when the mesa portion 60 between trench portions is miniaturized, the trench contact portion 200 can be easily provided.

The bottom surface of the trench contact portion 200 of the present example is in contact with the dummy trench portion 30. The dummy conductive portion 34 of the dummy trench portion 30 is connected to the emitter electrode 52 inside the trench contact portion 200. Accordingly, an emitter potential can be applied to the dummy conductive portion 34.

The side surface and the bottom surface of the trench contact portion 200 of the present example are in contact with the contact region 15. That is, the bottom surface of the trench contact portion 200 may be covered with the contact region 15 except for a portion in contact with the dummy trench portion 30, and the side surface of the trench contact portion 200 may be covered with the contact region 15 except for a portion in contact with a first emitter portion which will be described below. Accordingly, a hole current flowing toward the front surface 21 side of the semiconductor substrate 10 can be extracted, so that latch-up can be suppressed.

In FIG. 3, the side surface of the trench contact portion 200 is illustrated perpendicular to the front surface 21 of the semiconductor substrate 10, but may be inclined. In addition, the bottom surface of the trench contact portion 200 is illustrated in a shape curved downward, but may be flat. The side surface and the bottom surface of the trench contact portion 200 are merely distinguished for convenience, and a portion where an outer surface of the trench contact portion 200 extends in the depth direction from the front surface 21 of the semiconductor substrate 10 may be a side surface, and a portion which has an extending direction different from that of the side surface and connects side surfaces may be a bottom surface.

The emitter region 12 of the present example includes a first emitter portion 81 of the N+ type and a second emitter portion 82 of the N type. The emitter region 12 may further include a third emitter portion 83 of the N+ type. The first emitter portion 81 is provided in contact with the front surface 21 of the semiconductor substrate 10. The first emitter portion 81 of the present example is provided in contact with a side surface of the gate trench portion 40. The first emitter portion of the present example is provided in the X axis direction to extend from the gate trench portion 40 to the trench contact portion 200 provided above the dummy trench portion 30.

The second emitter portion 82 is provided below the first emitter portion 81 so as to be in contact with the first emitter portion 81. The second emitter portion 82 is a region of the N type having a doping concentration lower than that of the first emitter portion 81. The second emitter portion 82 of the present example is provided in contact with the side surface of the gate trench portion 40. The second emitter portion 82 of the present example is not in contact with the emitter electrode 52. A thickness Z2 of the second emitter portion 82 in the depth direction of the semiconductor substrate 10 in the present example is 0.1 μm or more and 1.5 μm or less. A width X2 of the second emitter portion 82 in the X axis direction in the present example is smaller than a width of the mesa portion 60 in the X axis direction. The width X2 of the second emitter portion 82 in the X axis direction of the present example may be, for example, 0.2 μm or more and 1.0 μm or less. In addition, the width X2 of the second emitter portion 82 in the X axis direction of the present example may be 20% or more and 80% or less of the width of the mesa portion 60 in the X axis direction.

The second emitter portion 82 of the present example has a doping concentration lower than that of the first emitter portion 81. This increases a resistance value of the second emitter portion 82. In addition, a current flowing between the first emitter portion 81 and the base region 14 passes through the second emitter portion 82. Therefore, the second emitter portion 82 of the present example functions as a resistance portion, and can suppress a saturation current flowing through a MOS structure. In addition, providing the emitter region 12 elongated in the Y axis direction increases a total emitter width in the Y axis direction and reduces the ON voltage. As described above, by providing the second emitter portion 82 functioning as a resistance portion, it is possible to achieve both a low saturation current and a low ON voltage.

The third emitter portion 83 is provided below the second emitter portion 82 so as to be in contact with the second emitter portion 82. The third emitter portion 83 is a region of the N+ type having a doping concentration higher than that of the second emitter portion 82. The third emitter portion 83 may have a doping concentration lower than that of the first emitter portion 81. The third emitter portion 83 of the present example is provided in contact with the side surface of the gate trench portion 40. The third emitter portion 83 of the present example is not in contact with the emitter electrode 52.

In the depth direction of the semiconductor substrate 10, an upper end of the gate conductive portion 44 of the gate trench portion 40 is arranged to face the third emitter portion 83. The upper end of the gate conductive portion 44 may refer to an upper end of its side surface facing the mesa portion 60. The upper end of the gate conductive portion 44 and the third emitter portion 83 facing each other means that the upper end of the gate conductive portion 44 is arranged between a position of an upper end and a position of a lower end of the third emitter portion 83 in the Z axis direction. The upper end and the lower end of the third emitter portion 83 may refer to an upper end and a lower end of its portion in contact with the side surface of the gate trench portion 40.

When the ON voltage is applied to the gate conductive portion 44, electrons are attracted to a region of the mesa portion 60 that faces the gate conductive portion 44, in a boundary portion between the mesa portion 60 and the trench portion. When the second emitter portion 82 and the gate conductive portion 44 are arranged to face each other, electrons are also attracted to a boundary portion of the second emitter portion 82. Since the second emitter portion 82 has a low doping concentration, a resistance value at the boundary portion may vary due to the attracted electrons. To address this variation, the third emitter portion 83 is arranged to face the upper end of the gate conductive portion 44, whereby it is possible to suppress the variation in the resistance value at the boundary portion of the second emitter portion 82. In addition, since the third emitter portion 83 has a high doping concentration, even if electrons are attracted to a boundary portion of the third emitter portion 83, the variation in the resistance value at the boundary portion is extremely small.

The first emitter portion 81 of the present example is in contact with the trench contact portion 200. Accordingly, a connection resistance between the emitter electrode 52 and the first emitter portion 81 can be reduced. The first emitter portion 81 may be in contact with an upper end of the contact region 15 at the side surface of the trench contact portion 200.

The second emitter portion 82 is not in contact with the trench contact portion 200. A dielectric film or a region of the P type may be provided between the second emitter portion 82 and the trench contact portion 200. The second emitter portion 82 of the present example is provided in contact with the contact region 15 provided on the side surface of the trench contact portion 200. Such a configuration can prevent a current from flowing between the emitter electrode 52 and the second emitter portion 82 through a path other than the first emitter portion 81.

The third emitter portion 83 is not in contact with the trench contact portion 200. A dielectric film or a P type region may be provided between the third emitter portion 83 and the trench contact portion 200. The third emitter portion 83 of the present example is provided in contact with the contact region 15 provided on the side surface of the trench contact portion 200. Such a configuration can prevent a current having passed through a channel of the base region 14 from flowing to the emitter electrode 52 without passing through the second emitter portion 82.

The gate trench portion 40 of the present example has a dummy conductive portion 84 at the emitter potential which is provided above the gate conductive portion 44 in the trench. The dummy conductive portion 84 of the present example is provided between the front surface 21 of the semiconductor substrate 10 and the gate conductive portion 44. The dummy conductive portion 84 of the present example is covered on its side surface by the gate dielectric film 42 and is insulated from the semiconductor substrate 10. An intermediate dielectric film 85 is provided between a lower end of the dummy conductive portion 84 and the gate conductive portion 44 in the present example, and the dummy conductive portion 84 is insulated from the gate conductive portion 44. The intermediate dielectric film 85 may be formed of a same material as that of the gate dielectric film 42. A thickness of the intermediate dielectric film 85 may be 0.05 μm or more and 0.2 μm or less.

In the depth direction of the semiconductor substrate 10, the lower end of the dummy conductive portion 84 is arranged at a position facing the third emitter portion 83. That is, the dummy conductive portion 84 of the present example is arranged at a position facing the second emitter portion 82 provided above the third emitter portion 83.

As described above, when the ON voltage is applied to the gate conductive portion 44, electrons are attracted to the region of the mesa portion 60 that faces the gate conductive portion 44, in the boundary portion between the mesa portion 60 and the trench portion. In this regard, by arranging the third emitter portion 83 to face the upper end of the gate conductive portion 44, it is possible to suppress the variation in the resistance value due to attraction of electrons to the second emitter portion 82 having a low doping concentration.

However, when the third emitter portion 83 is provided, a thickness of the entire emitter region 12 increases, so that positions of the base region 14 and the accumulation region 16 become relatively deep. Therefore, an acceleration voltage of ion implantation may increase, and a load of a process may increase. Furthermore, since a distance from a lower end of the channel to a lower end of the gate trench portion 40 is shortened, the ON voltage may increase.

In the semiconductor device 100 of the present example, by arranging the dummy conductive portion 84 of the gate trench portion 40 at a position facing the second emitter portion 82, it is possible to prevent electrons from being attracted in the second emitter portion 82 under an influence of the gate conductive portion 44 when the ON voltage is applied to the gate conductive portion 44.

Similarly to the gate conductive portion 44, the dummy conductive portion 84 of the present example is formed of polysilicon which is a conductive material. An upper end of the dummy conductive portion 84 of the present example is covered with the interlayer dielectric film 38. In another example, the dummy conductive portion 84 may be formed of a same material as that of the emitter electrode 52.

A formation process of the gate trench portion 40 of the present example will be described. A trench is formed at the front surface of the semiconductor substrate 10, and the gate dielectric film 42 is formed on a side surface and a bottom surface of the trench. Next, in the trench, polysilicon is filled on the gate dielectric film 42 to form the gate conductive portion 44. Next, the intermediate dielectric film 85 is formed at the upper end of the gate conductive portion 44. Next, polysilicon is grown on the intermediate dielectric film 85 to form the dummy conductive portion 84.

The dummy trench portions 30 may also be formed by a similar process. That is, the dummy trench portion 30 may also include the dummy conductive portion 84 provided above the dummy conductive portion 34 and the intermediate dielectric film 85 provided at the lower end of the dummy conductive portion 84. Accordingly, the gate trench portion 40 and the dummy trench portion 30 can be formed by a same process. In another example, the dummy trench portion 30 does not have the dummy conductive portion 84, and the interlayer dielectric film 38 may be provided above the dummy conductive portion 34.

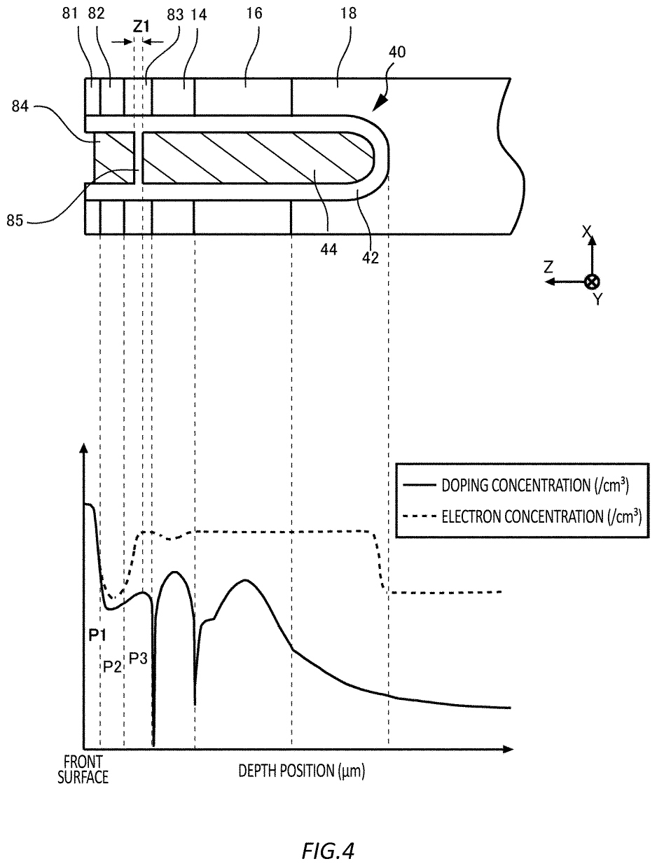

FIG. 4 illustrates a relationship between the doping concentration distribution and an electron concentration distribution according to an example. A horizontal axis of a graph indicates a depth position (a position in the −Z axis direction) starting from the front surface 21 of the semiconductor substrate 10. A solid line plot shows the doping concentration distribution in the semiconductor substrate 10, and a broken line plot shows the electron concentration distribution when the saturation current is flowing. For reference, an XZ cross section near the gate trench portion 40 is shown alongside the graph.

First, the doping concentration distribution will be described. The doping concentration distribution illustrated in FIG. 4 has a portion P1 corresponding to the first emitter portion 81, a portion P2 corresponding to the second emitter portion 82, and a portion P3 corresponding to the third emitter portion 83. The doping concentration distribution illustrated in FIG. 4 further includes portions respectively corresponding to the base region 14, the accumulation region 16, and the drift region 18, following P3.

The doping concentration distribution P1 of the first emitter portion 81 and the doping concentration distribution P3 of the third emitter portion 83 each have an upwardly convex profile and have a peak portion. The peak portion is a portion where the doping concentration shows a local maximum value. The peak portion of P3 may be lower than the peak portion of P1. That is, the doping concentration of the third emitter portion 83 may be lower than a maximum doping concentration of the first emitter portion 81.

The doping concentration distribution P2 of the second emitter portion 82 is a portion between P1 and P3. P2 may have a valley portion. The valley portion is a portion where the doping concentration shows a local minimum value. P2 has a positive slope from the valley portion toward the peak portion of P3. P2 may have a flat portion partially extending from the valley portion to the peak portion of P3. The flat portion is a portion where the doping concentration does not substantially change. P2 may have a peak portion lower than the peak portion of P3 between the valley portion and the peak portion of P3.

A maximum doping concentration of the third emitter portion 83 in the present example is 3 times or more and 1000 times or less a minimum doping concentration of the second emitter portion 82, and is lower than the maximum doping concentration of the first emitter portion 81. In the third emitter portion 83 of the present example, a thickness of a portion having a doping concentration that is 2 times or more the minimum doping concentration of the second emitter portion 82 is 0.05 μm or more and 1.5 μm or less.

Next, the electron concentration distribution will be described. When the ON voltage is applied to the gate trench portion 40, electrons are induced at a silicon interface facing the gate conductive portion 44. An electron concentration when the saturation current is flowing is substantially constant at a depth position of the gate conductive portion 44. The electron concentration rapidly decreases upward from the upper end of the gate conductive portion 44 and shows a local minimum value in the second emitter portion 82. Since the gate trench portion 40 of the present example has the dummy conductive portion 84 at the emitter potential at the position facing the second emitter portion 82, the electron concentration decreases in this manner, whereby it is possible to prevent electrons from being attracted in the second emitter portion 82.

A thickness Z1 of the intermediate dielectric film 85 of the present example is 0.05 μm or more and 0.2 μm or less. By setting the thickness Z1 within this range, it is possible to reliably reduce the electron concentration in the second emitter portion 82 while insulating the gate conductive portion 44 and the dummy conductive portion 84.

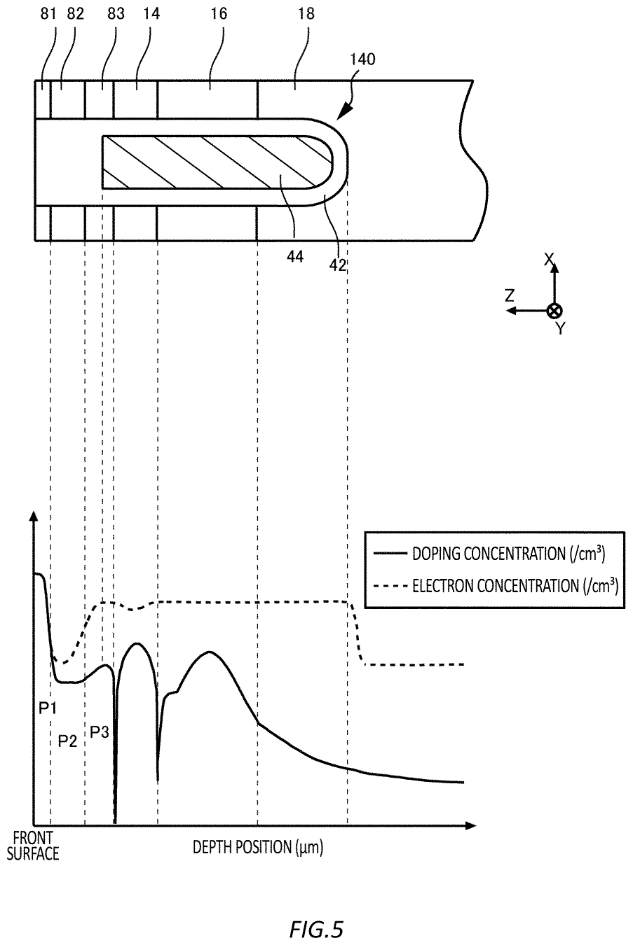

FIG. 5 illustrates a relationship between the doping concentration distribution and the electron concentration distribution according to a comparative example. A gate trench portion 140 of FIG. 5 is different from the gate trench portion 140 of FIG. 4 in not including the dummy conductive portion 84. In the gate trench portion 140, the interlayer dielectric film 38 may be embedded above the gate conductive portion 44.

The electron concentration distribution illustrated in FIG. 5 shows substantially a same profile as that of the electron concentration distribution illustrated in FIG. 4 in the gate conductive portion 44 and below the gate conductive portion 44. However, although the electron concentration decreases upward from the upper end of the gate conductive portion 44, a slope thereof is smaller than that of the electron concentration distribution in FIG. 4. This is because the gate trench portion 140 in FIG. 5 does not have the dummy conductive portion 84. Therefore, in the gate trench portion 140 of FIG. 5, by increasing the thickness of the second emitter portion 82 and sliding the electron concentration distribution in the depth direction, a local minimum value of the electron concentration is aligned within the second emitter portion 82, and electrons are prevented from being attracted in the second emitter portion 82.

As a result, according to the comparative example of FIG. 5, the thickness of the entire emitter region 12 increases, and the positions of the base region 14 and the accumulation region 16 become relatively deep. Therefore, the acceleration voltage of the ion implantation may increase, and the load of the process may increase. Furthermore, since the distance from the lower end of the channel to the lower end of the gate trench portion 40 is shortened, the ON voltage may increase.

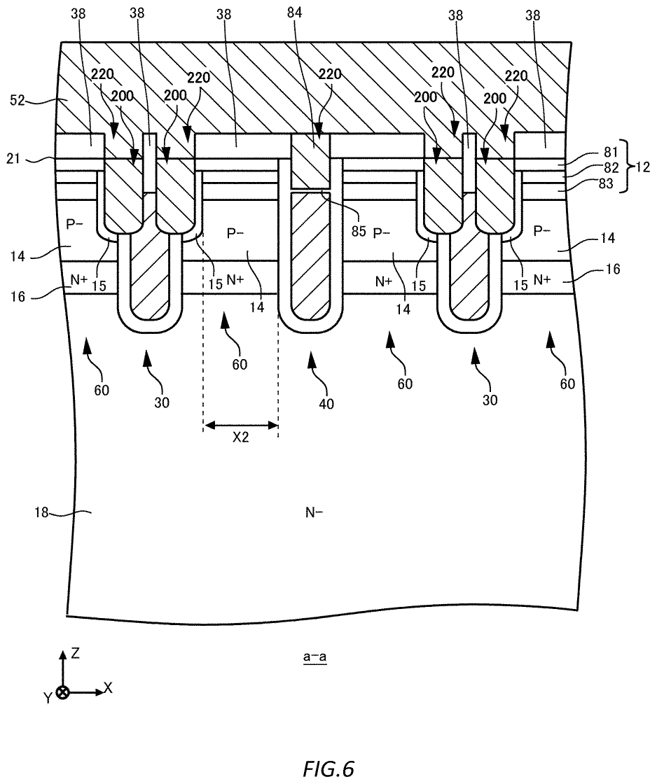

FIG. 6 is a view illustrating another example of the cross section taken along line a-a in FIG. 2. Here, differences from FIG. 3 will be mainly described. The dummy conductive portion 84 of the present example is formed of the same material as that of the emitter electrode 52. The dummy conductive portion 84 may be a tungsten plug provided in the contact hole 220. The dummy conductive portion 84 of the present example is connected to the emitter electrode 52 via the contact hole 220. Accordingly, the dummy conductive portion 84 can be formed by a same process as that of the emitter electrode 52.

The dummy conductive portion 84 is not provided in the dummy trench portion 30 of the present example. In the dummy trench portion 30, the interlayer dielectric film 38 may be embedded between the trench contact portions 200 above the dummy conductive portion 34.

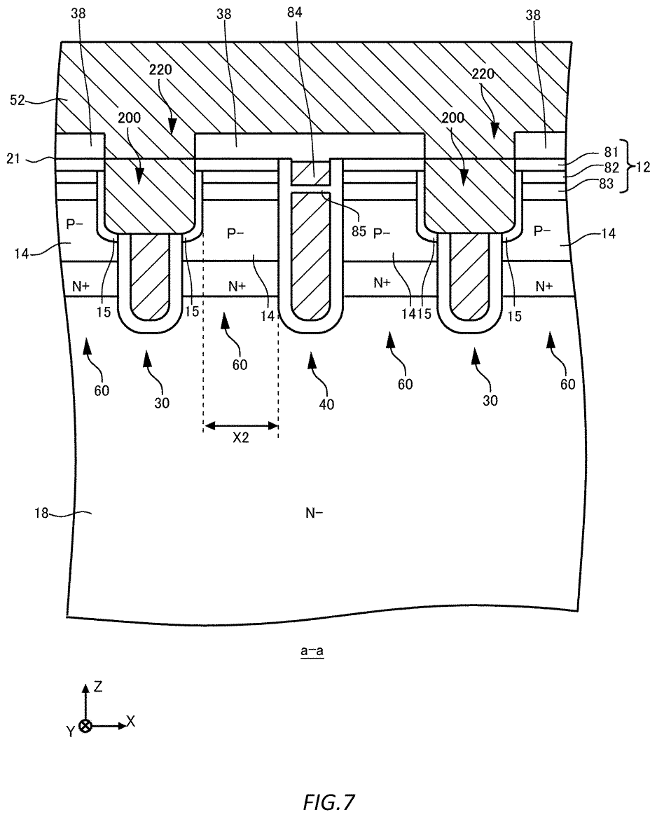

FIG. 7 is a view illustrating another example of the cross section taken along line a-a in FIG. 2. Here, differences from FIG. 3 will be mainly described. In FIG. 3, the plurality of trench contact portions 200 are provided above the dummy trench portion 30, but in FIG. 7, one trench contact portion 200 is provided above the dummy trench portion 30. The trench contact portion 200 of the present example is provided from one end to another end of the dummy trench portion 30 in the X axis direction to cover an upper end of the dummy trench portion 30. In the X axis direction, a width of the trench contact portion 200 may be larger than a width of the dummy trench portion 30.

Even with such a structure, effects similar to those of FIG. 3 can be obtained. Furthermore, since the width of the trench contact portion 200 of the present example is larger than the width of the trench contact portion 200 of FIG. 3, filling with a conductive material becomes easier.

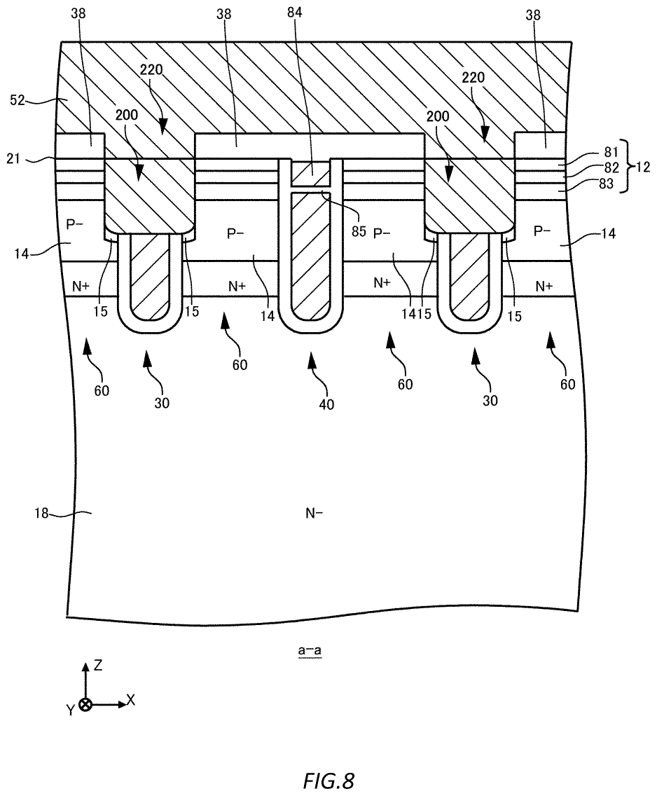

FIG. 8 is a view illustrating another example of the cross section taken along line a-a in FIG. 2. Here, differences from FIG. 3 will be mainly described. The contact region 15 of the present example is provided in contact with the bottom surface of the trench contact portion 200, and is not provided on the side surface of the trench contact portion 200. Similarly to the first emitter portion 81, the second emitter portion 82 and the third emitter portion 83 of the present example are provided in contact with the side surface of the trench contact portion 200. In another example, the contact region 15 may be provided below the third emitter portion 83 on the side surface of the trench contact portion 200.

The doping concentrations of the second emitter portion 82 and the third emitter portion 83 in the present example are set such that the second emitter portion 82 and the third emitter portion 83 are in Schottky contact with the emitter electrode 52 in the trench contact portion 200. Accordingly, electron injection from the emitter electrode 52 in the trench contact portion 200 to the second emitter portion 82 can be prevented, and the second emitter portion 82 can function as a resistance portion.

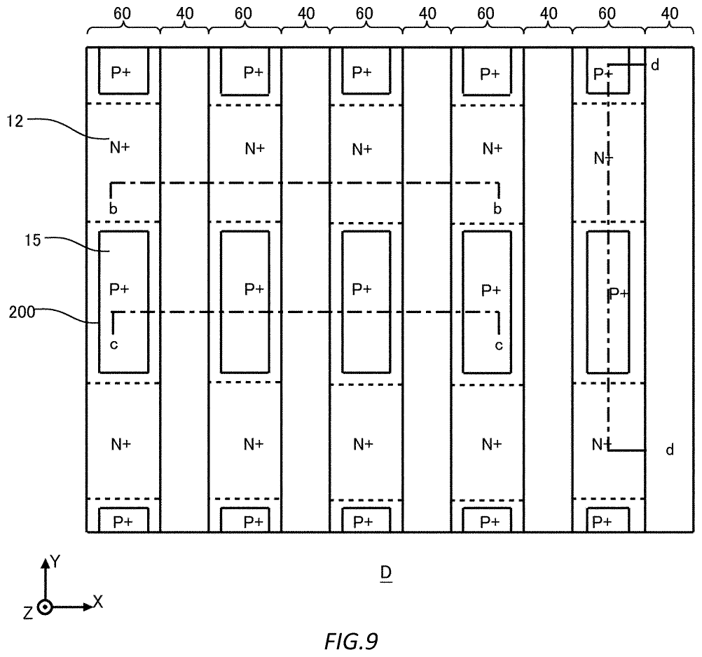

FIG. 9 is another example of the enlarged view of the region D in FIG. 1. The interlayer dielectric film 38 and the emitter electrode 52 are provided above the front surface 21 of the semiconductor substrate 10, but are omitted in FIG. 9. In the present example, in a top view of the semiconductor substrate 10, in the mesa portion 60, the contact regions 15 discretely provided and the emitter regions 12 provided in portions where the contact regions 15 are not provided are periodically arrayed. As will be described below, since the trench contact portions 200 are discretely provided in the mesa portion, the contact regions 15 provided on the bottom surfaces of the trench contact portions 200 are exposed, and the emitter regions 12 and the contact regions 15 are periodically arrayed in the Y axis direction. In FIG. 9, the end portion of the contact region 15 arranged below the emitter region 12 is indicated by a broken line.

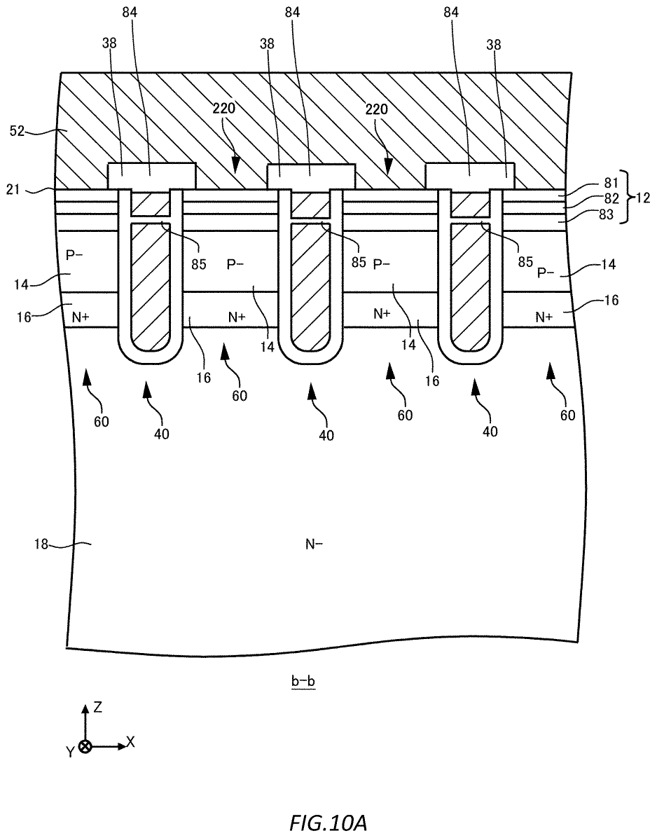

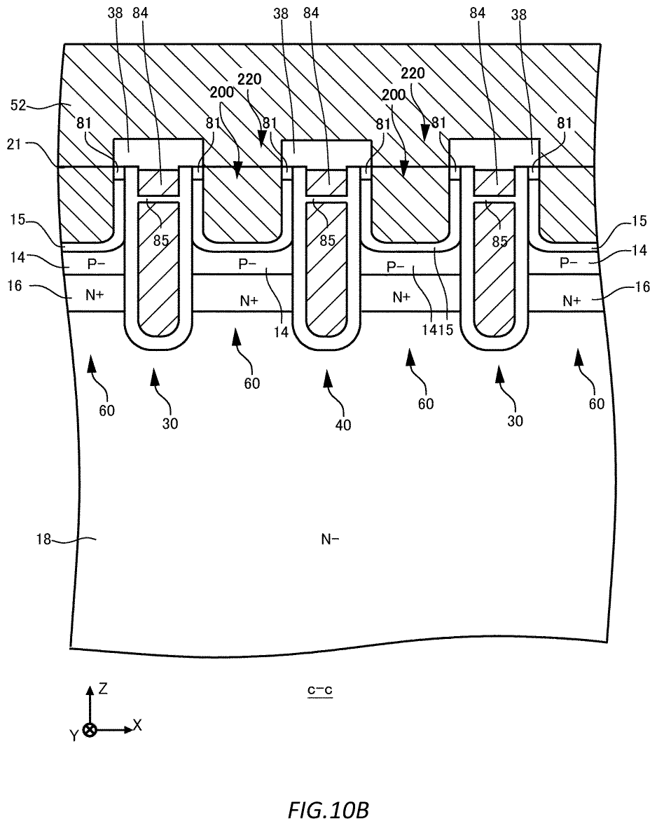

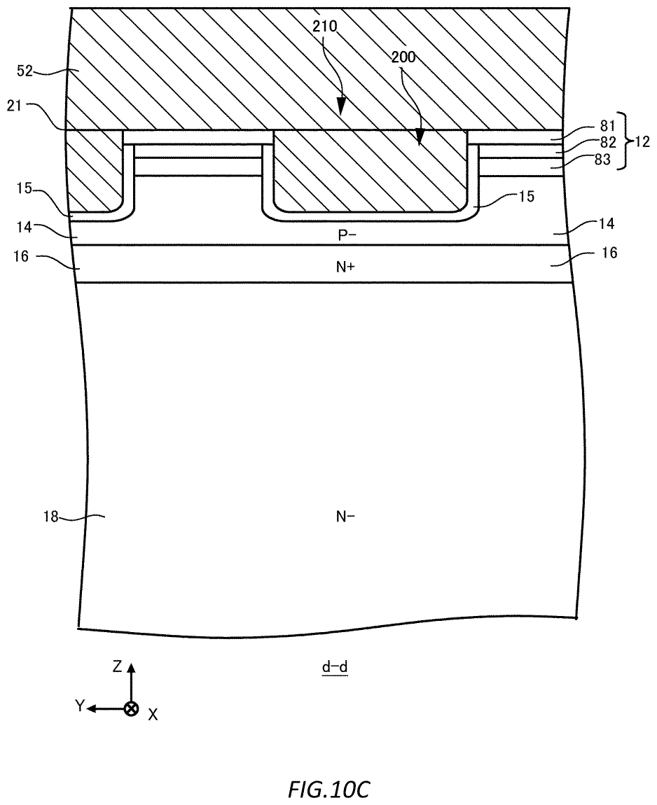

FIG. 10A is a view illustrating an example of a cross section taken along line b-b in FIG. 9. The cross section taken along line b-b in FIG. 9 is an XZ cross section which passes through the emitter region 12 and the gate trench portion 40 and does not pass through the trench contact portion 200. In FIG. 10A, all the trench portions are illustrated as the gate trench portion 40, but in another example, the trench portion adjacent to the gate trench portion 40 may be the dummy trench portion 30.

The contact hole 220 of the present example is provided above the mesa portion 60. As illustrated in FIG. 10A, in a portion where the trench contact portion 200 is not provided below the contact hole 220, all of the first emitter portion 81, the second emitter portion 82, and the third emitter portion 83 are provided over the mesa portion 60 in the X axis direction.

FIG. 10B is a view illustrating an example of a cross section taken along line c-c in FIG. 9. The cross section taken along line c-c in FIG. 9 is an XZ cross section which passes through the trench contact portion 200 and the contact region 15 in addition to the emitter region 12 and the gate trench portion 40. The trench contact portion 200 of the present example is provided below the contact hole 220 in the mesa portion 60. The contact region 15 of the present example is provided in contact with the side surface and the bottom surface of the trench contact portion 200. The first emitter portion 81 of the present example is provided above the contact region 15 in contact with the side surface of the trench contact portion 200. The contact region 15 of the present example is provided below the first emitter portion 81 from the side surface of the trench contact portion 200 to the side surface of the adjacent gate trench portion 40.

In another example, the second emitter portion 82 and the third emitter portion may be provided between the contact region 15 provided on the side surface of the trench contact portion 200 and the side surface of the gate trench portion 40. Accordingly, the total emitter width in the Y axis direction can be increased, and the ON voltage can be reduced.

FIG. 10C is a view illustrating an example of a cross section taken along line d-d in FIG. 9. The cross section taken along line d-d in FIG. 9 is a YZ cross section which passes through the contact hole 220 in the mesa portion 60. The trench contact portions 200 of the present example are discretely provided in the mesa portion 60 in the Y axis direction. In a portion where the trench contact portion 200 is provided, the contact region 15 provided on the side surface and the bottom surface of the trench contact portion 200 is electrically connected to the emitter electrode 52. In a portion where the trench contact portion 200 is not provided, the second emitter portion 82 and the third emitter portion 83 are provided in contact with the contact region 15.

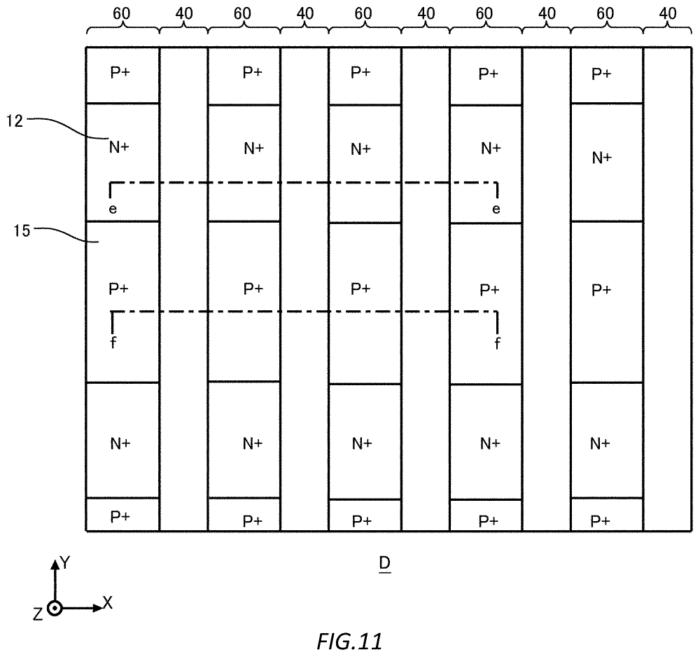

FIG. 11 is another example of the enlarged view of the region D in FIG. 1. The interlayer dielectric film 38 and the emitter electrode 52 are provided above the front surface 21 of the semiconductor substrate 10, but are omitted in FIG. 11. In the present example, in a top view of the semiconductor substrate 10, the emitter regions 12 and the contact regions 15 are alternately arranged in the mesa portion 60. In the present example, the trench contact portion 200 is not provided as will be described below.

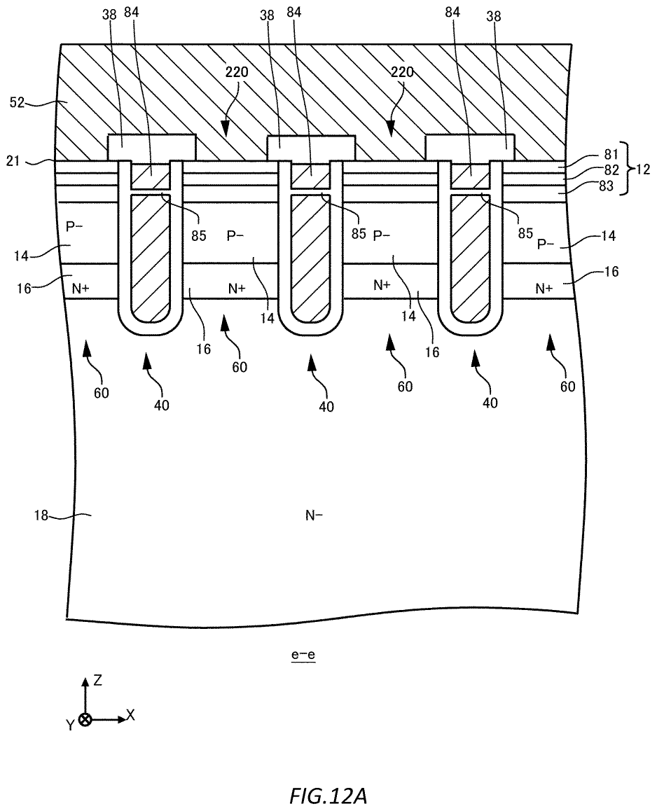

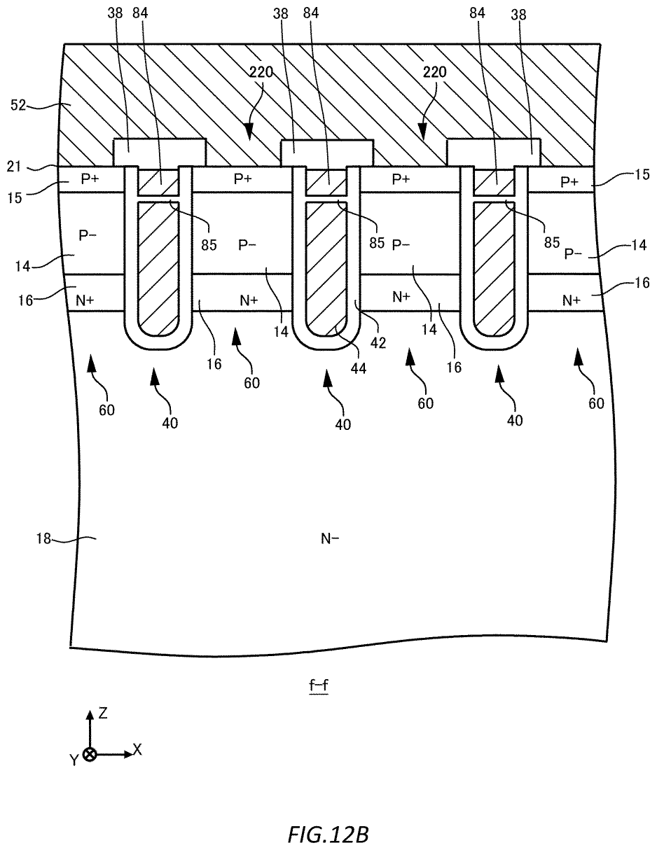

FIG. 12A is a view illustrating an example of a cross section taken along line e-e in FIG. 9. The cross section taken along line e-e in FIG. 9 is an XZ cross section which passes through the emitter region 12. The contact hole 220 of the present example is provided above the mesa portion 60.

FIG. 12B is a view illustrating an example of a cross section taken along line f-f in FIG. 9. The cross section taken along line f-f in FIG. 9 is an XZ cross section which passes through the contact region 15. The contact region 15 of the present example is provided at the front surface 21 of the semiconductor substrate 10.

With such a structure, even if the trench contact portion 200 is not provided, the contact region 15 can be provided at the front surface of the semiconductor substrate 10 to increase the total emitter width in the Y axis direction and reduce the ON voltage while securing a contact area with the emitter electrode 52 in the contact hole 220.

While the present invention has been described above by way of the embodiments, the technical scope of the present invention is not limited to the scope described in the above-described embodiments. It is apparent to persons skilled in the art that various alterations or improvements can be made to the above-described embodiments. It is also apparent from the description of the claims that the form to which such alterations or improvements are made can be included in the technical scope of the present invention.

It should be noted that the operations, procedures, steps, stages, and the like of each process performed by an apparatus, system, program, and method shown in the claims, the specification, or the drawings can be realized in any order as long as the order is not indicated by “prior to,” “before,” or the like and as long as the output from a previous process is not used in a later process. Even if the operation flow is described by using phrases such as “first” or “next” for the sake of convenience in the claims, specification, and drawings, it does not necessarily mean that the process must be performed in this order.

### Item 1

A semiconductor device including:
a drift region of a first conductivity type which is provided in a semiconductor substrate;
a plurality of trench portions which extend in a predetermined trench extending direction at a front surface of the semiconductor substrate;
a base region of a second conductivity type which is provided above the drift region;
an emitter region of the first conductivity type which is provided above the drift region and has a doping concentration higher than that of the drift region;
a contact region of the second conductivity type which is provided above the drift region and has a doping concentration higher than that of the base region;
an interlayer dielectric film which is provided above the semiconductor substrate and has a contact hole; and
an emitter electrode which is provided above the semiconductor substrate and is in contact with the semiconductor substrate via the contact hole, wherein
the plurality of trench portions include a gate trench portion including a gate conductive portion and a gate dielectric film,
the emitter region includes
a first emitter portion which is in contact with the front surface of the semiconductor substrate,
a second emitter portion which is provided below the first emitter portion and has a doping concentration lower than that of the first emitter portion, and
a third emitter portion which is provided below the second emitter portion and has a doping concentration higher than that of the second emitter portion, and
the gate trench portion includes
a dummy conductive portion at an emitter potential, which is provided above the gate conductive portion, in a trench.

### Item 2

The semiconductor device according to item 1, wherein
a doping concentration distribution of the second emitter portion in a depth direction of the semiconductor substrate has any one of a flat portion in which a doping concentration does not substantially change, a valley portion in which a doping concentration shows a local minimum value, or a peak portion in which a doping concentration shows a local maximum value and is lower than the doping concentration of the third emitter portion.

### Item 3

The semiconductor device according to item 1, wherein
the doping concentration of the third emitter portion is lower than a maximum doping concentration of the first emitter portion.

### Item 4

The semiconductor device according to item 1, wherein
a thickness of the second emitter portion in a depth direction of the semiconductor substrate is 0.1 μm or more and 1.5 μm or less.

### Item 5

The semiconductor device according to item 1, wherein
a width of the second emitter portion in a trench array direction is 20% or more and 80% or less of a width of a mesa portion in the trench array direction.

### Item 6

The semiconductor device according to item 1, wherein
an intermediate dielectric film is provided between the gate conductive portion and the dummy conductive portion, and
a thickness of the intermediate dielectric film is 0.05 μm or more and 0.2 μm or less.

### Item 7

The semiconductor device according to item 1, wherein
in a depth direction of the semiconductor substrate, an upper end of the gate conductive portion is arranged at a position facing the third emitter portion.

### Item 8

The semiconductor device according to item 1, wherein
in a depth direction of the semiconductor substrate, a lower end of the dummy conductive portion is arranged at a position facing the third emitter portion.

### Item 9

The semiconductor device according to item 1, wherein
an upper end of the dummy conductive portion is covered with the interlayer dielectric film.

### Item 10

The semiconductor device according to item 1, wherein
the dummy conductive portion is connected to the emitter electrode via the contact hole.

### Item 11

The semiconductor device according to item 1, wherein
a maximum doping concentration of the third emitter portion is 3 times or more and 1000 times or less a minimum doping concentration of the second emitter portion, and is lower than a maximum doping concentration of the first emitter portion.

### Item 12

The semiconductor device according to item 1, wherein
in the third emitter portion, a thickness in a depth direction of the semiconductor substrate of a portion having a doping concentration that is 2 times or more a minimum doping concentration of the second emitter portion is 0.05 μm or more and 1.5 μm or less.

### Item 13

The semiconductor device according to item 1, including
a trench contact portion which is provided below the contact hole from the front surface of the semiconductor substrate to an inside of the semiconductor substrate, wherein
the plurality of trench portions include a dummy trench portion, and
the trench contact portion is provided above the dummy trench portion.

### Item 14

The semiconductor device according to item 13, wherein
a width of the second emitter portion in a trench array direction is smaller than a width of a mesa portion in the trench array direction.

### Item 15

The semiconductor device according to item 13, wherein
the first emitter portion is provided in contact with the trench contact portion, and
the second emitter portion and the third emitter portion are provided apart from the trench contact portion.

### Item 16

The semiconductor device according to item 13, including
a plurality of trench contact portions above the dummy trench portion.

### Item 17

The semiconductor device according to item 13, wherein
the trench contact portion is provided from one end to another end of the dummy trench portion in a trench array direction to cover an upper end of the dummy trench portion.

### Item 18

The semiconductor device according to item 13, wherein
the first emitter portion is provided in a trench array direction to extend from the gate trench portion to the trench contact portion provided above the dummy trench portion.

### Item 19

The semiconductor device according to item 13, wherein
the contact region is provided in contact with a side surface and a bottom surface of the trench contact portion.

### Item 20

The semiconductor device according to item 19, wherein
the first emitter portion is provided in contact with the trench contact portion, and
the second emitter portion and the third emitter portion are provided in contact with the contact region provided on the side surface of the trench contact portion.

### Item 21

The semiconductor device according to item 19, wherein
emitter regions equivalent to the emitter region are discretely arranged in a trench extending direction,
contact regions equivalent to the contact region are discretely arranged in the trench extending direction so as to overlap the emitter regions in a top view of the semiconductor substrate, and
a width of the contact region in the trench extending direction is larger than a width of the emitter region in the trench extending direction.

### Item 22

The semiconductor device according to item 13, wherein
the second emitter portion and the third emitter portion are in Schottky contact with the emitter electrode in the trench contact portion.

### Item 23

The semiconductor device according to item 22, wherein
the contact region is provided in contact with a bottom surface of the trench contact portion.

### Item 24

The semiconductor device according to item 19, wherein
all of the first emitter portion, the second emitter portion, and the third emitter portion are provided in contact with a side surface of the trench contact portion.

### Item 25

The semiconductor device according to item 1, wherein
the contact hole is provided above a mesa portion, and
the semiconductor device includes a trench contact portion which is provided below the contact hole from the front surface of the semiconductor substrate to an inside of the semiconductor substrate.

### Item 26

The semiconductor device according to item 25, wherein
trench contact portions equivalent to the trench contact portion are discretely arranged in a trench extending direction.

### Item 27

The semiconductor device according to item 25, wherein
the contact region is provided in contact with a side surface and a bottom surface of the trench contact portion,
the first emitter portion is provided above the contact region in contact with a side surface of the trench contact portion, and
the second emitter portion and the third emitter portion are provided in contact with the contact region.

### Item 28

The semiconductor device according to item 27, wherein
the contact region is provided in contact with the gate trench portion.

### Item 29

The semiconductor device according to item 1, wherein
the contact hole is provided above a mesa portion, and
the emitter region and the contact region are alternately provided at the front surface of the semiconductor substrate in the mesa portion.

### EXPLANATION OF REFERENCES

10: semiconductor substrate; 11: p type outer circumferential well region; 12: emitter region; 14: base region; 15: contact region; 16: accumulation region; 18: drift region; 20: buffer region; 21: front surface; 22: collector region; 23: back surface; 24: collector electrode; 30: dummy trench portion; 32: dummy dielectric film; 34: dummy conductive portion; 38: interlayer dielectric film; 40: gate trench portion; 42: gate dielectric film; 44: gate conductive portion; 52: emitter electrode; 60: mesa portion; 70: transistor portion; 81: first emitter portion; 82: second emitter portion; 83: third emitter portion; 84: dummy conductive portion; 85: intermediate dielectric film; 90: edge termination structure portion; 100: semiconductor device; 130: gate runner; 140: gate trench portion; 160: active portion; 161: first end side; 162: second end side; 164: gate pad; 200: trench contact portion; and 220: contact hole.

What is claimed is:

1. A semiconductor device comprising:
a drift region of a first conductivity type which is provided in a semiconductor substrate;
a plurality of trench portions which extend in a predetermined trench extending direction at a front surface of the semiconductor substrate;
a base region of a second conductivity type which is provided above the drift region;
an emitter region of the first conductivity type which is provided above the drift region and has a doping concentration higher than that of the drift region;
a contact region of the second conductivity type which is provided above the drift region and has a doping concentration higher than that of the base region;
an interlayer dielectric film which is provided above the semiconductor substrate and has a contact hole; and
an emitter electrode which is provided above the semiconductor substrate and is in contact with the semiconductor substrate via the contact hole, wherein
the plurality of trench portions include a gate trench portion including a gate conductive portion and a gate dielectric film,
the emitter region includes
a first emitter portion which is in contact with the front surface of the semiconductor substrate,
a second emitter portion which is provided below the first emitter portion and has a doping concentration lower than that of the first emitter portion, and
a third emitter portion which is provided below the second emitter portion and has a doping concentration higher than that of the second emitter portion, and
the gate trench portion includes
a dummy conductive portion at an emitter potential, which is provided above the gate conductive portion, in a trench.

2. The semiconductor device according to claim 1, wherein
a doping concentration distribution of the second emitter portion in a depth direction of the semiconductor substrate has any one of a flat portion in which a doping concentration does not substantially change, a valley portion in which a doping concentration shows a local minimum value, or a peak portion in which a doping concentration shows a local maximum value and is lower than the doping concentration of the third emitter portion.

3. The semiconductor device according to claim 1, wherein
the doping concentration of the third emitter portion is lower than a maximum doping concentration of the first emitter portion.

4. The semiconductor device according to claim 1, wherein
a thickness of the second emitter portion in a depth direction of the semiconductor substrate is 0.1 μm or more and 1.5 μm or less.

5. The semiconductor device according to claim 1, wherein
a width of the second emitter portion in a trench array direction is 20% or more and 80% or less of a width of a mesa portion in the trench array direction.

6. The semiconductor device according to claim 1, wherein
an intermediate dielectric film is provided between the gate conductive portion and the dummy conductive portion, and
a thickness of the intermediate dielectric film is 0.05 μm or more and 0.2 μm or less.

7. The semiconductor device according to claim 1, wherein
in a depth direction of the semiconductor substrate, an upper end of the gate conductive portion is arranged at a position facing the third emitter portion.

8. The semiconductor device according to claim 1, wherein
in a depth direction of the semiconductor substrate, a lower end of the dummy conductive portion is arranged at a position facing the third emitter portion.

9. The semiconductor device according to claim 1, wherein
an upper end of the dummy conductive portion is covered with the interlayer dielectric film.

10. The semiconductor device according to claim 1, wherein
the dummy conductive portion is connected to the emitter electrode via the contact hole.

11. The semiconductor device according to claim 1, wherein
a maximum doping concentration of the third emitter portion is 3 times or more and 1000 times or less a minimum doping concentration of the second emitter portion, and is lower than a maximum doping concentration of the first emitter portion.

12. The semiconductor device according to claim 1, wherein
in the third emitter portion, a thickness in a depth direction of the semiconductor substrate of a portion having a doping concentration that is 2 times or more a minimum doping concentration of the second emitter portion is 0.05 μm or more and 1.5 μm or less.

13. The semiconductor device according to claim 1, comprising
a trench contact portion which is provided below the contact hole from the front surface of the semiconductor substrate to an inside of the semiconductor substrate, wherein
the plurality of trench portions include a dummy trench portion, and
the trench contact portion is provided above the dummy trench portion.

14. The semiconductor device according to claim 13, wherein
a width of the second emitter portion in a trench array direction is smaller than a width of a mesa portion in the trench array direction.

15. The semiconductor device according to claim 13, wherein
the first emitter portion is provided in contact with the trench contact portion, and
the second emitter portion and the third emitter portion are provided apart from the trench contact portion.

16. The semiconductor device according to claim 13, comprising
a plurality of trench contact portions above the dummy trench portion.

17. The semiconductor device according to claim 13, wherein
the trench contact portion is provided from one end to another end of the dummy trench portion in a trench array direction to cover an upper end of the dummy trench portion.

18. The semiconductor device according to claim 13, wherein
the first emitter portion is provided in a trench array direction to extend from the gate trench portion to the trench contact portion provided above the dummy trench portion.

19. The semiconductor device according to claim 13, wherein
the contact region is provided in contact with a side surface and a bottom surface of the trench contact portion.

20. The semiconductor device according to claim 19, wherein
the first emitter portion is provided in contact with the trench contact portion, and
the second emitter portion and the third emitter portion are provided in contact with the contact region provided on the side surface of the trench contact portion.

21. The semiconductor device according to claim 19, wherein
emitter regions equivalent to the emitter region are discretely arranged in a trench extending direction,
contact regions equivalent to the contact region are discretely arranged in the trench extending direction so as to overlap the emitter regions in a top view of the semiconductor substrate, and
a width of the contact region in the trench extending direction is larger than a width of the emitter region in the trench extending direction.

22. The semiconductor device according to claim 1, wherein
the contact hole is provided above a mesa portion, and
the semiconductor device includes a trench contact portion which is provided below the contact hole from the front surface of the semiconductor substrate to an inside of the semiconductor substrate.

23. The semiconductor device according to claim 1, wherein
the contact hole is provided above a mesa portion, and
the emitter region and the contact region are alternately provided at the front surface of the semiconductor substrate in the mesa portion.
